(19) United States
(12) Patent Application Publication
(10) Pub. No.: US 2023/0005387 A1
(43) Pub. Date: Jan. 5, 2023

(54) ELECTRONICS CIRCUIT BOARD DESIGN TOOL

(71) Applicant: SLIM CIRCUITS PTY LTD, Adamstown Heights, New South Wales (AU)

(72) Inventors: Graham Maxwell Mitchell, Adamstown, New South Wales (AU); Christopher Arthur Hildebrandt, Millfield, New South Wales (AU); Michael Erwin Ruppe, New Lambton, New South Wales (AU)

(21) Appl. No.: 17/778,555

(22) PCT Filed: Nov. 20, 2020
(86) PCT No.: PCT/AU2020/051261

§ 371 Date: May 20, 2022

(30) Foreign Application Priority Data
Nov. 22, 2019 (AU) 2019904417

(51) Int. Cl. G09B 23/18; H05K 3/30; B23K 26/03; B23K 26/042

(52) U.S. Cl. CPC G09B 23/183; H05K 3/306; B23K 26/032; B23K 26/042; H05K 2203/167; B23K 26/382

(57) ABSTRACT

Described herein is an electronics circuit board design tool. The tool includes a substantially planar non-conductive substrate adapted to be positioned on an electronics breadboard. The substrate includes a plurality of guide apertures at locations corresponding to predefined electrical inputs of the breadboard such that electronic components are able to be connected to the electronics breadboard through respective ones of the guide apertures. The tool also includes indicia printed on a surface of substrate. The indicia is indicative of the type or position of electrical connections or components to be connected with the breadboard through corresponding ones of the guide apertures.

### CROSS-REFERENCE TO RELATED APPLICATIONS

This application is a national phase entry of, and claims priority to, International Patent Application No. PCT/AU2020/051261 (filed 20 Nov. 2020), which claims priority to Australian Patent Application No. 2019904417 (filed 22 Nov. 2019). The entire contents of these applications are incorporated herein by reference.

### FIELD OF THE INVENTION

The present application relates to electronic circuit design and in particular to an electronics circuit board design tool.

Embodiments of the present invention are particularly adapted for educating people on how to build electronic circuits on an electronics prototyping board. However, it will be appreciated that the invention is applicable in broader contexts and other applications.

### BACKGROUND

Existing techniques for educating people about the operation of electronic circuits are classical educational experiences based on digital/drawn schematics or illustrations of component connections and tools. Typically, a user references an electronic schematic and seeks to replicate the schematic physically with components and an electronics prototyping board (or “breadboard”).

This method is error-prone; it relies on the user's memory of connection details, manual dexterity and requires reasonably good eyesight. It is easy for a user to misplace a connection due to the small-scale and density of breadboard connection points.

Comparing a partially constructed circuit to a separate illustration is a high cognitive-load task; e.g. it can be difficult to identify that a component may be missing.

The inventors have identified that there is a need to address the above problems to improve education of the building of electronic circuits.

Any discussion of the background art throughout the specification should in no way be considered as an admission that such art is widely known or forms part of common general knowledge in the field.

### SUMMARY OF THE INVENTION

In accordance with a first aspect of the present invention, there is provided an electronics circuit board design tool including:
a substantially planar non-conductive substrate adapted to be positioned on an electronics breadboard;
a plurality of guide apertures disposed in the substrate at locations corresponding to predefined electrical inputs of the breadboard such that electronic components are able to be connected to the breadboard through respective ones of the guide apertures; and
indicia printed on a surface of the substrate, the indicia indicative of the type or position of electrical connections or components to be connected with the breadboard through corresponding ones of the guide apertures.

In some embodiments, outer dimensions of the substrate are matched to a typical electronics breadboard.

Preferably the guide apertures are precision cut using a laser.

In some embodiments, the indicia include information indicative of a type of electronic component to be inserted into the breadboard at a specific location. In some embodiments, the indicia include information indicative of an electrical characteristic of an electronic component to be inserted into the breadboard at a specific location. In some embodiments, the indicia include information indicative of a polarity of electronic components to be connected to the breadboard. In some embodiments, the indicia include colour coding indicative of electronic components.

In some embodiments, the substrate is formed of a polymer material. In other embodiments, the substrate is formed of a paper-based material.

Preferably the substrate has a thickness of between 0.095 mm and 3 mm, inclusive.

In accordance with a second aspect of the present invention, there is provided a method of fabricating an electronics circuit board design tool, the method including:
i. generating a digital design template including one or more electronics templates and each electronics template includes electronics component indicia indicative of a type and/or position of electrical connections or components to be connected with an electronics breadboard;
ii. printing the digital design template onto a substrate material;
iii. controlling a laser cutting device to cut holes in the substrate material at predetermined locations on the one or more electronics templates to generate guide apertures;
iv. controlling the laser cutting device to cut the one or more electronics templates from the substrate material to produce one or more electronics circuit board design tools.

In some embodiments, step i. includes using a digital representation of an electronics breadboard for aligning template indicia with electrical connections of the electronics breadboard.

In some embodiments, the digital design template includes image data and machine control instructions for the laser cutting device.

Preferably the substrate includes a plurality of electronics templates and the method produces a corresponding plurality of electronics circuit board design tools.

In some embodiments, the laser cutting device includes a camera configured to identify alignment indicia on the substrate material and make controlled movements relative to the position of the alignment indicia.

In some embodiments, the substrate material is formed of a polymer material. In other embodiments, the substrate material is formed of a paper-based material.

### BRIEF DESCRIPTION OF THE FIGURES

Example embodiments of the disclosure will now be described, by way of example only, with reference to the accompanying drawings in which:

FIG. 1 is an elevated perspective view of an electronics circuit board design tool positioned over an electronics prototyping breadboard;

FIG. 2 is a side schematic view of the electronics circuit design tool and breadboard of FIG. 1 with electronic components installed thereon;

FIG. 3 illustrates example indicia for building a simple electronic circuit;

FIG. 4 illustrates a partially connected electrical circuit using the electronics design tool illustrated in FIG. 3 in position on an electronics prototyping board;

FIG. 5 is a process flow diagram illustrating the primary steps in a method of fabricating an electronics circuit board design tool;

FIG. 6 is a screenshot of a digital design template being created in a digital illustration program;

FIG. 7 is a screenshot of an example vector-art digital representation of a breadboard displayed in a digital illustration program;

FIG. 8 is a photograph of an exemplary printed substrate material illustrating a design template with two unique circuit designs;

FIG. 9 is a photograph illustrating a laser cutting device performing a cutting process on a substrate material; and

FIG. 10 is a photograph of the reverse side of an electronics circuit design tool showing hole-placement.

### DESCRIPTION OF THE INVENTION

Device Overview

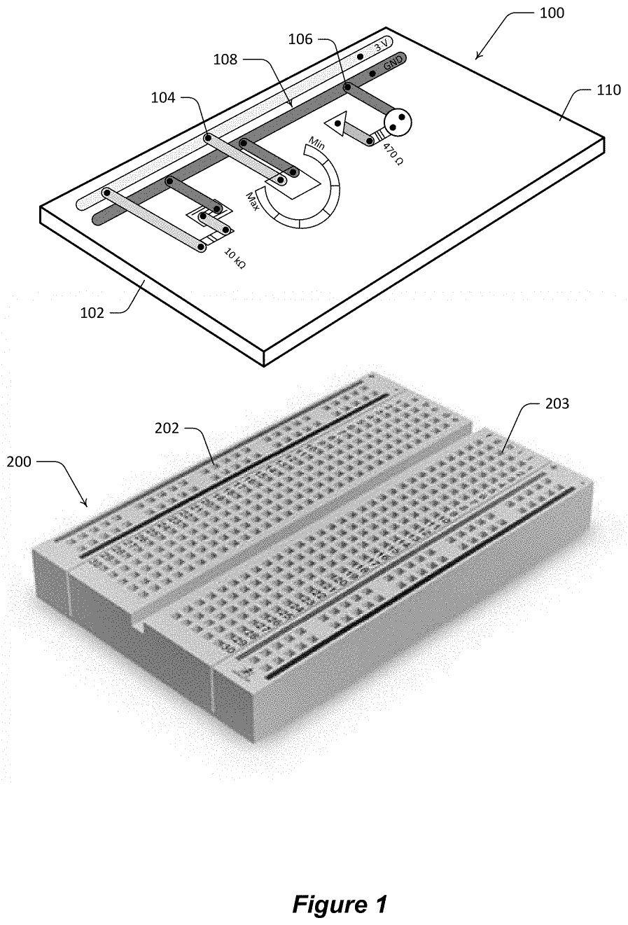

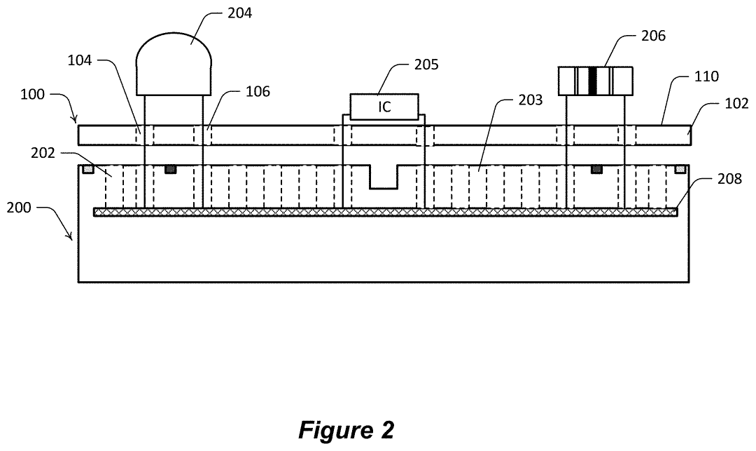

Referring to FIGS. 1 and 2, described herein is an electronics circuit board design tool 100. Tool 100 is configured to be adhered, attached or simply situated onto an upper surface of a conventional and commercially available electronics prototyping breadboard 200.

Tool 100 includes a substantially planar non-conductive substrate 102 having outer dimensions that closely match breadboard 200. Substrate may be formed of a polymer material such as polyester or plastics material, or a paper-based material suitable for printing thereon. In some embodiments, substrate 102 is formed of a polyester based medium such as called NeverTear, which is manufactured by Fuji Xerox Co. Ltd. In other embodiments, substrate 102 is formed of a polyethylene fibre-based medium such as the Tyvek® product manufactured by DuPont de Nemours, Inc. In further embodiments, substrate 102 is formed of a synthetic waterproof paper medium such as Teslin® waterproof paper, manufactured by PP Industries, Inc. In still further embodiments, substrate 102 is formed of other commercially available paper-based materials such as 210 GSM gloss paper. In another embodiment, substrate 102 is formed of a transparent plastic material similar in properties to overhead-projector transparency. In general, the material selected for substrate 102 should be non-conductive, moisture-resistant and be able to be printed on. It is also preferable for substrate 102 to be tear-resistant and able to be laser-cut.

To match the dimensions of a traditional breadboard, substrate 102 is cut to have dimensions of about 16.3 cm long by 5.3 cm wide. However, it will be appreciated that breadboards come in different sizes and the specific dimensions of substrate 102 may vary depending on the design requirements. Preferably, substrate 102 has a thickness of between 0.095 mm and 3 mm, inclusive. This thickness provides substrate 102 with sufficient strength or stiffness to maintain structural integrity while maintaining a small degree of flexibility. A thin profile also provides for easily inserting conductive electrical pins of electronic components through substrate 102. However, it will be appreciated that, in other embodiments, substrate 102 may have a thickness greater or less than the above range.

Substrate 102 includes a plurality of guide apertures, e.g. 104, 106, disposed therein at locations corresponding to predefined electrical through-hole inputs, e.g. 202 and 203, of breadboard 200. The alignment of guide apertures with electrical inputs provides for electronic components, e.g. 204-206, to be able to be connected to electronics breadboard 200 by inserting their electrical pins through respective ones of the guide apertures. As mentioned below, guide apertures 104, 106 may be positioned on substrate 102 at locations based on a dimensionally-accurate digital representation of a breadboard design reference to align the components over corresponding through-holes of the breadboard. Guide apertures have diameters sufficiently large so as to receive standard electrical pins of electronic components. This is typically in the range of 0.5 mm to 2 mm but, in some embodiments, may be within 1.5 mm. Guide apertures may have varying sized diameters to account for electronic components having different gauge electrical pins.

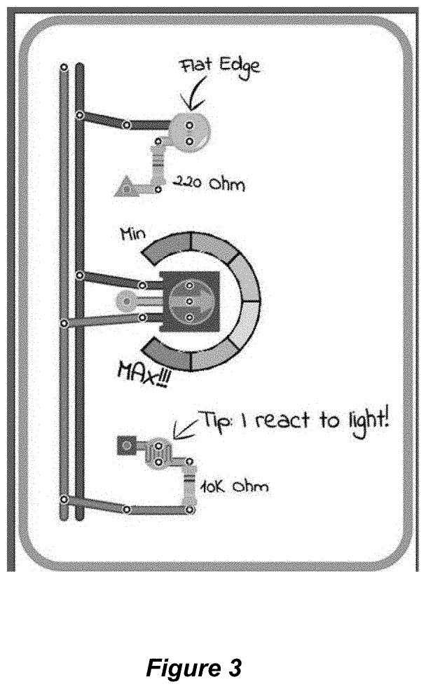

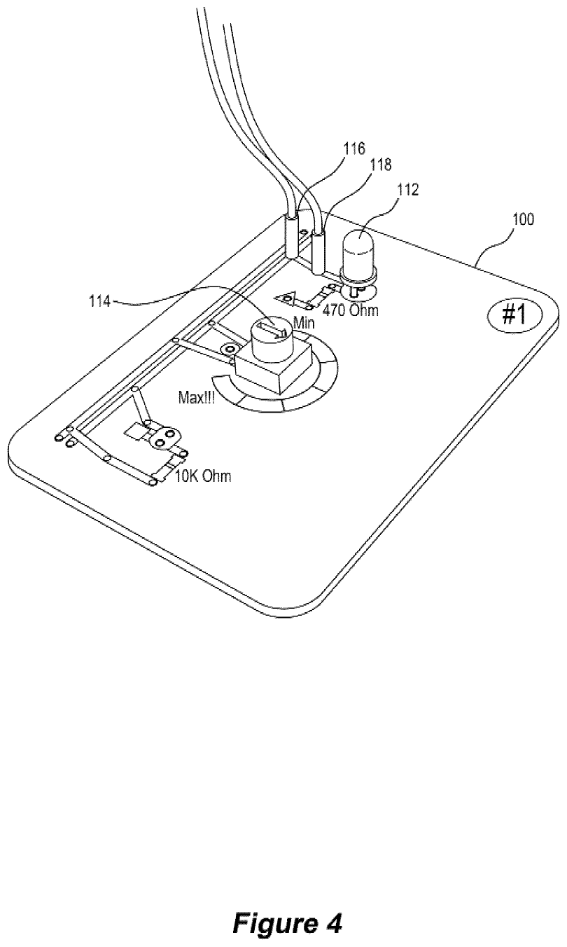

As illustrated in FIG. 1, tool 100 also includes indicia 108 printed on an upper surface 110 of the substrate. Indicia 108 is indicative of the type or position of electrical connections or components to be connected with breadboard 200 through corresponding ones of the guide apertures 104, 106. FIG. 3 illustrates example indicia for building a simple electronic circuit and FIG. 4 illustrates a partially connected electrical circuit using the electronics design tool illustrated in FIG. 3. As illustrated, the polymer or paper-based material allows additional indicia to be hand printed onto upper surface 110 of substrate 102 after manufacture of tool 100.

By way of example, indicia 108 may include information indicative of a type of electronic component to be inserted into the breadboard at a specific location, such as an LED 204, integrated circuit 205 or resistor 206. Indicia 108 may also include information indicative of an electrical characteristic of an electronic component to be inserted into breadboard 200 at a specific location, such as a resistance value of a resistor or voltage value of a voltage source. Indicia 108 may also include colour coding indicative of electronic components such as resistors, or colour ranges of variable parameter devices such as a dial. In some embodiments, indicia 108 includes information indicative of a polarity of electronic components to be connected to the breadboard, such as a voltage polarity. The indicia 108 may also include instructions to a user such as numerals to indicate an order of components to be connected to breadboard 200.

To use electronics design tool 100, breadboard 200 is first situated on a surface in an operable position. Tool 100 is then manually positioned on top of breadboard 200 by a user with outer dimensions of tool 100 aligned with those of breadboard 200. Aligning the tool edges to the breadboard edges aligns the guide apertures over the corresponding breadboard electrical through-hole inputs, as illustrated in FIG. 2.

With tool 100 positioned in an operative position on breadboard 200, the user then inserts the first electronics component through the corresponding guide apertures indicated by indicia 108 and engages the electrical pins with the associated through-hole inputs 202 and 203 of breadboard 200. Typically, connection of a single electronics component having at least two electrical pins is sufficient to securely engage tool 100 onto breadboard 200, locking it against translation and rotation. Engagement of the electrical pins with through-hole inputs 202 connects those pins with underlying electrical connections of an interconnect layer 208 of breadboard 200, as illustrated in FIG. 2. This interconnect layer 208 facilitates the electrical connections between electronics components connected with breadboard 200. The size of the electrical pins and through-hole inputs 202 are such that the electrical pins have a snug fit arrangement to securely engage the electronics components and tool 100 onto breadboard 200.

Preferably, the user will insert larger electronics components first, such as an integrated circuit, which have a greater number of electrical pins. The greater number of pins provides for enhanced engagement of tool 100 with breadboard 200. If no large multi-pinned electronics components are required for a circuit, tool 100 may be engaged with breadboard 200 using the electrical fly-leads (such as DuPont style fly-leads manufactured by DuPont de Nemours, Inc.), which are present in every circuit to provide power to the electronics components.

In addition to the natural engagement via electrical pins described above, it may be advantageous to provide additional engagement means to engage tool 100 with breadboard 200. These additional engagement means may include an adhesive material or tape, rubber bands, clips, cable ties or other conventional fastening devices that are non-conducting.

With the first electronics component in place, tool 100 is secured to breadboard 200 and the user may connect additional electronics components to breadboard 200. The additional components are connected by inserting their respective electrical pins through the corresponding guide apertures of tool 100 in accordance with the indicia 108. The process is continued until the electronic circuit is complete.

Tool 100 may be reusable as connecting electronics components with assistance of the indicia 108 does not damage the card or components.

A partially completed electronics circuit created using tool 100 is illustrated in FIG. 4. The circuit includes an LED 112, voltage dial 114 and electrical fly-leads 116 and 118. As illustrated, tool 100 includes a colour scale indicia 120 for indicating a range of voltage positions of dial 114. The indicia on tool 100 also include resistor values and other helpful instructions and comments such as which side a “flat edge” of LED 112 should be oriented.

Manufacturing Process

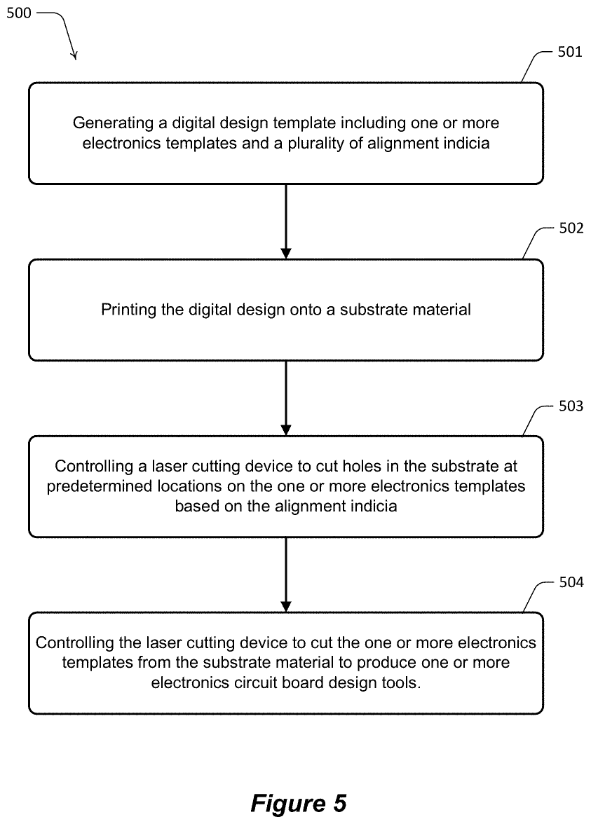

Referring now to FIGS. 5-10, a method 500 of fabricating electronics circuit board design tool 100 will be described.

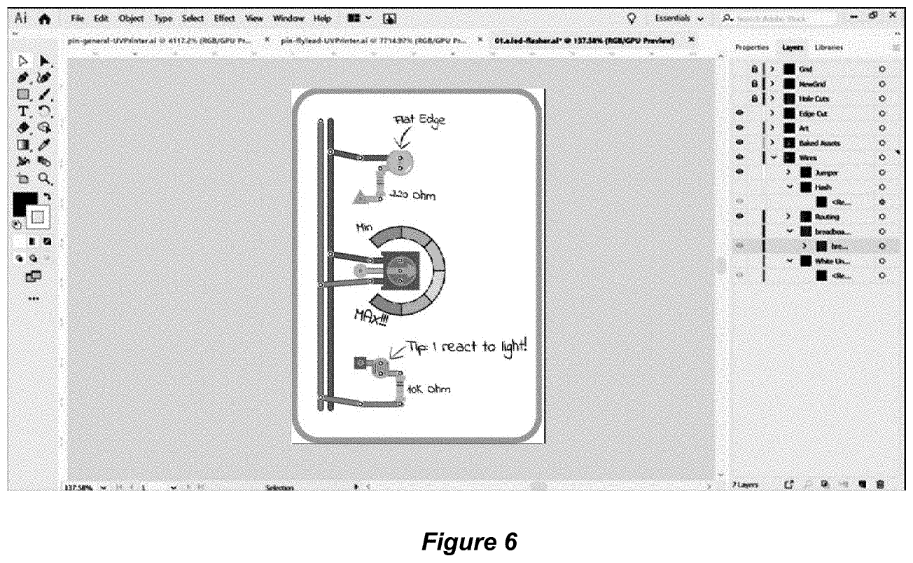

At step 501, method 500 includes generating a digital design template in a digital illustration program such as Adobe Illustrator, GIMP or a CAD program on a computer. An example digital design template being created in a digital illustration program is illustrated in FIG. 6. The digital design template includes one or more electronics templates corresponding to electronic circuits to be built and a plurality of alignment indicia for aligning a laser cutting device (described below). Each electronics template includes the electronics component indicia 108 indicative of a type or position of electrical connections or components to be connected with electronics breadboard 200.

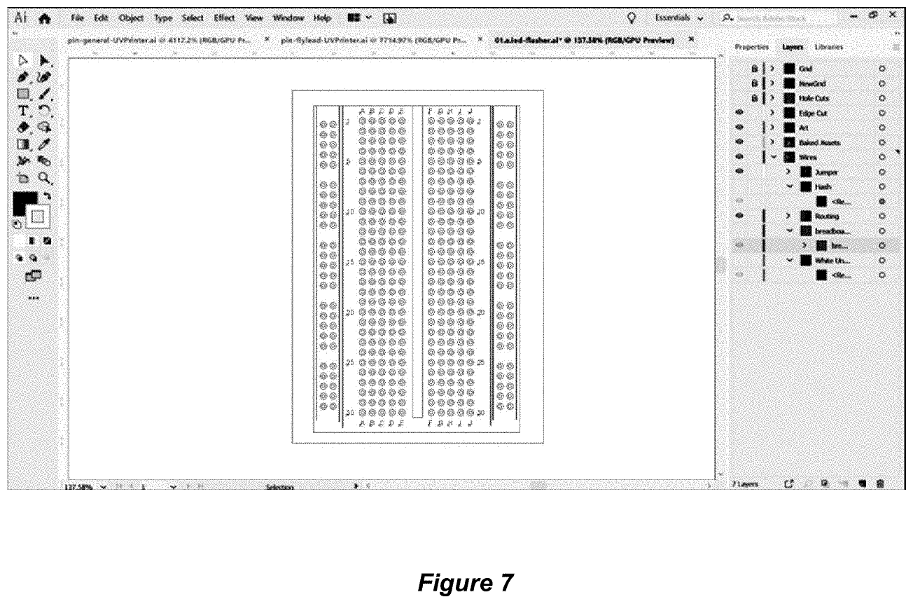

The indicia components are preferably drawn to actual-size in digital format, together with the tool outline and any title text required. Within the digital illustration program, a dimensionally-accurate digital representation of a breadboard is used as a design reference to align the components over corresponding through-holes of the breadboard. An example vector-art digital representation of a breadboard is illustrated in FIG. 7. In some embodiments, the digital breadboard representation is sourced from an open-source design software such as Fritzing, developed by Interaction Design Lab Potsdam.

Any connecting wires are also illustrated, and supporting indicia like helpful hints or graphics are included. The artwork is duplicated into a ‘panel,’ filling the space available on the print material. This final digital design template is appropriate for both CMYK printing the artwork onto a substrate, and for generating a cutting-program for the laser cutter. As such, the digital design template includes both image data and machine control instructions for a laser cutting device.

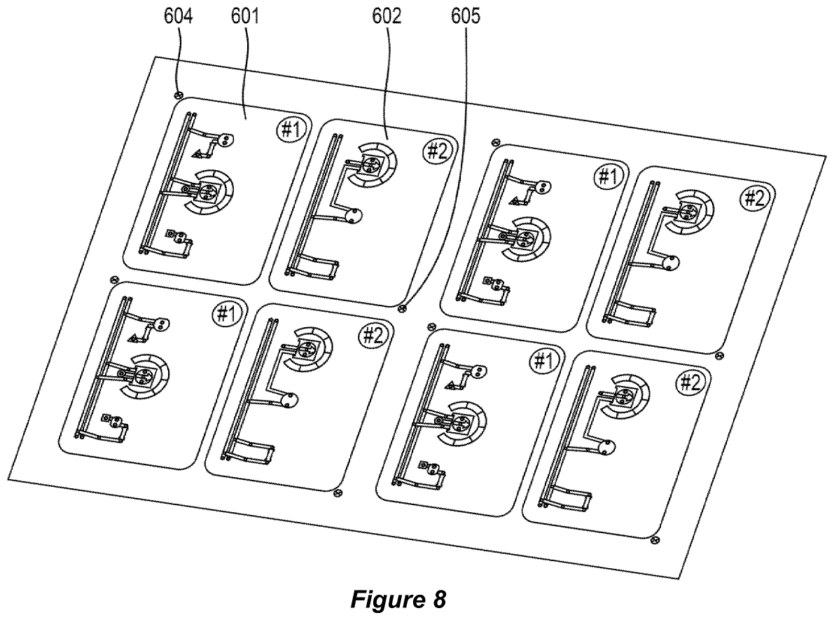

At step 502, the digital design template is printed at actual size onto a substrate material through a printing process. FIG. 8 illustrates an exemplary printed substrate material showing a design template with two different circuit designs 601 and 602, and local alignment (or “registration”) marks, e.g. 604 and 605 in the corners. However, it will be appreciated that the digital design template may include any number of different electronics templates indicative of different circuit designs.

The printing process of step 502 may include laser printing or flexible UV-curable printing to a substrate material such as NeverTear, Tyvek®, Teslin® or gloss paper material described above. Where the substrate material is a transparent plastic, a flexible UV-curable ink printing process may be preferable. Typically, a preferred ink technology may depend on what is recommended by the substrate material manufacturer to achieve a scratch-resistant and clean print. However, any recommended printing method should be sufficiently non-conductive to avoid short circuits between electronics components.

At step 503, a laser cutting device 700 is controlled to cut holes in the substrate material at predetermined locations on the one or more electronics templates to generate guide apertures. This process includes using alignment marks 604 and 605 to perform an optical alignment process in order to perform the laser cutting.

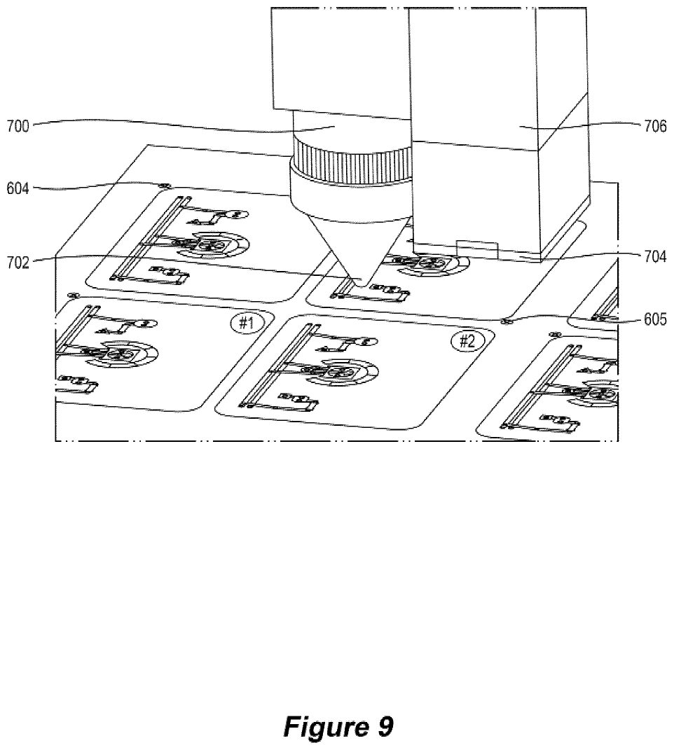

As shown in FIG. 9, laser cutting device 700 includes a laser head 702, alignment camera 704 and associated vision control system 706. In the illustrated embodiment, laser cutting device 700 is a Speedy 400 manufactured by Trotec Laser GmbH with a JobControl® vision control system add-on to perform the optical alignment. The vision control system 706 processes images from camera 704 to control a position of laser head 702 during the cutting process.

The vision control system 706 images alignment marks 604 and 605 and uses the relative position and orientation of these alignment marks 604 and 605 as reference points to perform optical alignment by determining the position and rotation of printed sheet material on the working area of the laser. However, it will be appreciated that other laser cutting systems may be implemented. In further embodiments, a non-laser based cutting system may be used to perform step 503 and step 504 described below.

The diameter of the holes cut in the substrate material may be fixed to a common diameter such as 0.76 mm. However, in some embodiments, the diameters vary to accommodate different electronics components. By way of example, holes corresponding to connections for electrical flyleads may be formed with a diameter of around 1 mm. The wider diameter also allows the wire to pull slightly to the side without upsetting the alignment of the substrate to the breadboard.

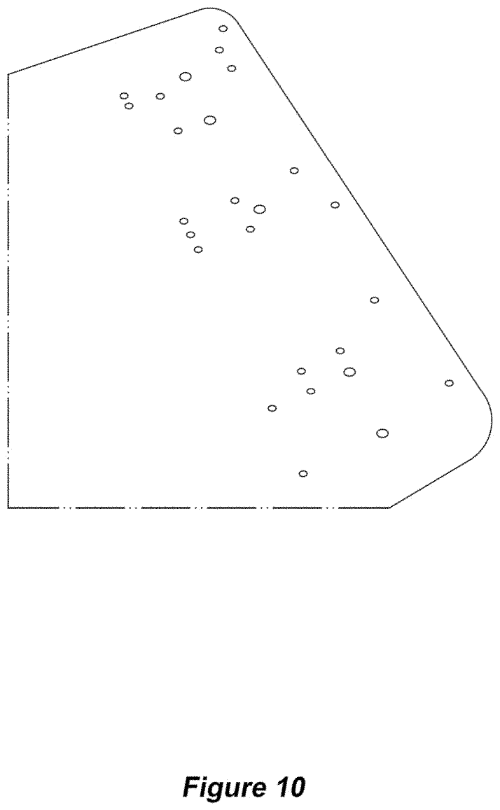

The holes are cut at locations corresponding to connection points of electronics components where electronic pins are to be inserted. FIG. 9 illustrates laser cutting device 700 performing a cutting process on the substrate material. FIG. 10 illustrates the reverse side of an electronics circuit design tool to show hole-placement clearly.

The holes are preferably precision cut using a laser as the position accuracy of the holes must closely match that of the corresponding breadboard through-holes. Preferably the cutting accuracy is equal to or better than 0.2 mm. However, in some embodiments, the cutting accuracy may be within about 0.5 mm.

At step 504, the laser cutting device 700 is controlled to cut the one or more electronics templates from the substrate material to produce one or more electronics circuit board design tools. This process involves controlling device 700 to cut around the outer edges of each electronics template by following a predefined tool path. During this process, camera 704 is again configured to image one or more alignment marks 604 and 605 and, in response, vision control system 706 configured to make controlled movements of laser head 702 relative to the position of the alignment mark. The tool path may start at a first alignment mark and end at a second alignment mark. As mentioned above, the control instructions for device 700 may be stored in the digital design template.

Thus, both the cutting of holes at step 503 and the cutting of the templates from the substrate at step 504 are guided by an alignment process of laser head 702 by imaging alignment marks 604 and 605 by camera 704 and controlling the position of laser head 702 using vision control system 706. In some embodiments, the cutting process of steps 503 and 504 can produce 5 to 10 electronics design tools per minute.

### CONCLUSIONS

It will be appreciated that the electronics design tool described above assists users in constructing electronic circuits by indicating where electronics components shall be placed on an electronics “breadboard.” The card is printed with colour graphics that represent electronics components, and cut with the appropriate pattern to match the connection pattern of these electronics components. Useful information is printed directly onto the card to ease points of confusion during the assembly process.

The combination of the precision cut substrate to match the breadboard, combined with the printed indicia allow the location of electronics components to be easily identified and connected together. Guidance for specific points of confusion are also printed on the substrate, contributing to a user's comprehension of electronics components. In using the electronics design tool described above, there is no need for a user to reference back and forth between a manual or tutorial.

Overlaying the tool on a breadboard reduces ‘visual noise’ by eliminating the regular pattern of breadboard connection points. Further, this overlaying gives a clear visual indication that a component is missing, since a component covers a corresponding illustration. This is particularly useful for users with limited vision. The design printed on each tool also shows relevant ‘hidden’ connections that exist within the breadboard, invisible to the user. These connections are often a point of confusion for beginners.

### INTERPRETATION

Reference throughout this specification to “one embodiment”, “some embodiments” or “an embodiment” means that a particular feature, structure or characteristic described in connection with the embodiment is included in at least one embodiment of the present disclosure. Thus, appearances of the phrases “in one embodiment”, “in some embodiments” or “in an embodiment” in various places throughout this specification are not necessarily all referring to the same embodiment. Furthermore, the particular features, structures or characteristics may be combined in any suitable manner, as would be apparent to one of ordinary skill in the art from this disclosure, in one or more embodiments.

As used herein, unless otherwise specified the use of the ordinal adjectives “first”, “second”, “third”, etc., to describe a common object, merely indicate that different instances of like objects are being referred to, and are not intended to imply that the objects so described must be in a given sequence, either temporally, spatially, in ranking, or in any other manner.

It should be appreciated that in the above description of exemplary embodiments of the disclosure, various features of the disclosure are sometimes grouped together in a single embodiment, Fig., or description thereof for the purpose of streamlining the disclosure and aiding in the understanding of one or more of the various inventive aspects. This method of disclosure, however, is not to be interpreted as reflecting an intention that the claims require more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this disclosure.

Furthermore, while some embodiments described herein include some but not other features included in other embodiments, combinations of features of different embodiments are meant to be within the scope of the disclosure, and form different embodiments, as would be understood by those skilled in the art. For example, in the following claims, any of the claimed embodiments can be used in any combination.

In the description provided herein, numerous specific details are set forth. However, it is understood that embodiments of the disclosure may be practiced without these specific details. In other instances, well-known methods, structures and techniques have not been shown in detail in order not to obscure an understanding of this description.

Similarly, it is to be noticed that the term coupled, when used in the claims, should not be interpreted as being limited to direct connections only. The terms “coupled” and “connected,” along with their derivatives, may be used. It should be understood that these terms are not intended as synonyms for each other. Thus, the scope of the expression a device A coupled to a device B should not be limited to devices or systems wherein an output of device A is directly connected to an input of device B. It means that there exists a path between an output of A and an input of B which may be a path including other devices or means. “Coupled” may mean that two or more elements are either in direct physical, electrical or optical contact, or that two or more elements are not in direct contact with each other but yet still co-operate or interact with each other.

Embodiments described herein are intended to cover any adaptations or variations of the present invention. Although the present invention has been described and explained in terms of particular exemplary embodiments, one skilled in the art will realize that additional embodiments can be readily envisioned that are within the scope of the present invention.

1. An electronics circuit board design tool including:
a substantially planar non-conductive substrate adapted to be positioned on an electronics breadboard;
a plurality of guide apertures disposed in the substrate at locations corresponding to predefined electrical inputs of the breadboard such that electronic components are able to be connected to the breadboard through respective ones of the guide apertures; and
indicia printed on a surface of the substrate, the indicia indicative of the type or position of electrical connections or components to be connected with the breadboard through corresponding ones of the guide apertures.

2. The design tool according to claim 1 wherein outer dimensions of the substrate are matched to a typical electronics breadboard.

3. The design tool according to claim 1 wherein the guide apertures are precision cut using a laser.

4. The design tool according to claim 1 wherein the indicia include information indicative of a type of electronic component to be inserted into the breadboard at a specific location.

5. The design tool according to claim 1 wherein the indicia include information indicative of an electrical characteristic of an electronic component to be inserted into the breadboard at a specific location.

6. The design tool according to claim 1 wherein the indicia include information indicative of a polarity of electronic components to be connected to the breadboard.

7. The design tool according to claim 1 wherein the indicia include colour coding indicative of electronic components.

8. The design tool according to claim 1 wherein the substrate is formed of a polymer material.

9. The design tool according to claim 1 wherein the substrate is formed of a paper-based material.

10. The design tool according to claim 1 wherein the substrate has a thickness of between 0.095 mm and 3 mm, inclusive.

11. A method of fabricating an electronics circuit board design tool, the method including:
i. generating a digital design template including one or more electronics templates and each electronics template includes electronics component indicia indicative of a type and/or position of electrical connections or components to be connected with an electronics breadboard;
ii. printing the digital design template onto a substrate material;
iii. controlling a laser cutting device to cut holes in the substrate material at predetermined locations on the one or more electronics templates to generate guide apertures;
iv. controlling the laser cutting device to cut the one or more electronics templates from the substrate material to produce one or more electronics circuit board design tools.

12. The method according to claim 11 wherein step i. includes using a digital representation of an electronics breadboard for aligning template indicia with electrical connections of the electronics breadboard.

13. The method according to claim 11 wherein the digital design template includes image data and machine control instructions for the laser cutting device.

14. The method according to claim 11 wherein the substrate includes a plurality of electronics templates and the method produces a corresponding plurality of electronics circuit board design tools.

15. The method according to claim 11 wherein the laser cutting device includes a camera configured to identify alignment indicia and make controlled movements relative to the position of the alignment indicia.

16. The method according to claim 11 wherein the substrate material is formed of a polymer material.

17. The method according to claim 11 wherein the substrate material is formed of a paper-based material.
